(19) United States
(12) Patent Application Publication
(10) Pub. No.: US 2012/0037925 A1
(43) Pub. Date: Feb. 16, 2012

(54) Engineered Substrate for Light Emitting Diodes

(76) Inventor: Calvin W. Sheen, Derry, NH (US)

(21) Appl. No.: 13/198,129

(22) Filed: Aug. 4, 2011

Related U.S. Application Data
(60) Provisional application No. 61/372,392, filed on Aug. 10, 2010.

(51) Int. Cl. H01L 33/44

(52) U.S. Cl. 257/79; 438/45; 257/E33.06

(57) ABSTRACT

A diode substrate including a crystalline aluminum oxide window, a silicon oxide layer on the crystalline aluminum oxide window, and a silicon layer on the silicon oxide layer, the silicon layer being implanted with ions at a predetermined depth.

### CROSS-REFERENCE TO RELATED APPLICATIONS

This application claims the benefit of prior U.S. Application No. 61/372,392 filed Aug. 10, 2010, which is incorporated by reference herein in its entirety.

### BACKGROUND

Current technology for gallium nitride (GaN) light emitting diodes (LEDs) uses a window constructed from an aluminum oxide single crystal of a specific orientation (i.e., C-plane with slight off-cut, also referred to as sapphire). This oriented sapphire is particularly costly to produce because the natural crystal direction during large crystal growth is along a different axis. The as-grown crystals must be cored along the C-plane, then cut and polished.

To create an LED, a gallium nitride (GaN) structure is grown on the sapphire window. Once the GaN structure is epitaxially grown on the oriented sapphire, it is particularly difficult to release. Either laser induced decomposition and lift off or a complex chemical etch and lift off is required to release the GaN structure from the window. Because all of the epitaxy layers are chemically similar, selectivity for either the laser lift off (LLO) or chemical lift off (CLO) is very poor.

There is a need for an engineered substrate with a less costly window that allows for easier release of a GaN structure in an LED.

### SUMMARY

This application related to the field of substrates for light emitting diodes (LEDs).

It has been found that by forming a silicon layer on an aluminum oxide window, a substrate for a gallium nitride (GaN) light emitting diode (LED) can be formed. The silicon can act as an epitaxy seed layer, allowing the GaN crystals to be formed on its surface. Because the window is not the seed layer, the aluminum oxide window does not have to be in any particular orientation, producing a significant cost savings over the sapphire crystals in the prior art.

Methods of making these substrates are also described, herein. The methods can involve the deposition of silicon on a silicon oxide wafer. The wafer can then be bonded and annealed to the aluminum oxide window. The silicon layer can be subject to hydrogen and/or boron ion implantation, which can cause the silicon to cleave along a line representing the depth at which these ions are implanted.

Methods of forming GaN LEDs on the substrate through eiptaxy are also described, herein. Also described are methods of under etching the LEDs in order to easily remove LEDs from the substrate and further to recycle the substrate.

In general, in an aspect, implementations of the subject matter described herein can provide a diode substrate including a crystalline aluminum oxide window, a silicon oxide layer on the crystalline aluminum oxide window, and a silicon layer on the silicon oxide layer, the silicon layer being implanted with ions at a predetermined depth.

Implementations of the subject matter described herein can provide one or more of the following features. The silicon layer is between substantially 100 nm and substantially 1000 nm thick. The silicon oxide layer is between substantially 1 nm and substantially 1000 nm thick. The aluminum oxide window is between substantially 100 μm and substantially 10,000 μm thick. The silicon layer is cleaved at substantially the location of the implanted ions. The substrate further includes a laminate comprising an n-layer and a p-layer, the laminate being disposed on the silicon layer. The n-layer and p-layer laminate is configured as a light emitting diode.

In general, in another aspect, implementations of the subject matter described herein can provide a method of producing a diode substrate, the method including placing a layer of silicon oxide on a silicon wafer, implanting ions through the silicon oxide to a predetermined depth in the silicon wafer, activating one surface of each of the silicon oxide layer and an aluminum oxide window, bonding the activated surfaces of the silicon oxide layer and the aluminum oxide window to form a stack, annealing the stack, and heating the stack to cause the silicon wafer to cleave at substantially the location of the implanted ions.

Implementations of the subject matter described herein can provide one or more of the following features. The placing step includes placing a layer of silicon oxide on a silicon wafer by at least one of thermal oxide, chemical oxide, and deposited oxide methods. The ions are selected from the group consisting of Boron and Hydrogen ions. The activating includes activating the surfaces using plasma implantation of at least one of O₂ and N₂. The boding includes bonding at a temperature of between substantially 50° C. and substantially 150° C. The bonding includes applying a force of between substantially 5 kN and substantially 60 kN. The force is applied for between 1 second and 1 hour. The annealing takes place at a temperature less than substantially 150° C. Heating the stack to cause the silicon wafer to cleave includes heating the stack to a temperature between substantially 200° C. and substantially 250° C. The method further includes etching a surface of the silicon layer using a buffered oxide etch.

Implementations of the subject matter described herein can also provide one or more of the following features. The method further includes epitaxially growing crystals on the silicon layer to form one or more additional layers on the stack. The one or more additional layers are selected from the group consisting of an n-layer and a p-layer. The crystals are chosen from the group consisting of Mg:GaN, InGaN, Si:GaN, and SiNₓ. The crystals are configured as a light emitting diode. The method further includes undercutting the silicon layer under the crystal layer to release the one or more additional layers from the stack. The method further includes, after the one or more additional layers are released from the stack, wet etching to remove any remaining silicon from the stack. The method further includes, after any remaining silicon is removed, removing the silicon oxide layer from the aluminum oxide window using at least one of etching and polishing.

Various aspects of the current subject matter may provide one or more of the following capabilities. A GaN structure can be separated more easily from a substrate when compared with prior techniques. The cost of a window used to grow a GaN structure can be reduced. A substrate with a chemically dissimilar structure from a GaN structure can be created. Laser and chemical lift off procedures can be performed more easily when compared with prior techniques.

These and other capabilities of the current subject matter, along with the current subject matter itself, will be more fully understood after a review of the following figures, detailed description, and claims.

### BRIEF DESCRIPTION OF THE FIGURES

FIG. 1 is a schematic showing an engineered substrate for a gallium nitride (GaN) light emitting diode (LED).

FIG. 2 is a schematic showing an engineered substrate for a GaN LED.

FIG. 3 is a schematic showing boron and/or hydrogen ion implantation.

FIG. 4 is a schematic showing the bonding of the silicon oxide and silicon layers to the aluminum oxide window.

FIG. 5 is a schematic showing the cleavage of the silicon layer at the depth of boron and/or hydrogen ion implantation.

FIG. 6 is a schematic showing a substrate for a GaN LED with crystal layers formed on its surface by epitaxy.

FIG. 7 is a schematic showing LED devices formed out of the layers formed by epitaxy.

FIG. 8 is a schematic showing under etching of the LED devices.

FIG. 9 is a schematic showing removal of the LED devices from a substrate for a GaN LED.

FIG. 10 is a schematic showing recycling of a substrate for a GaN LED.

FIG. 11 is a block diagram of a process for making an engineered substrate.

FIG. 12 is a block diagram of a process for using engineered substrates.

### DETAILED DESCRIPTION

Implementations of the current subject matter provide techniques for providing an engineered substrate for a gallium nitride (GaN) light emitting diode (LED). The engineered substrate preferably includes a layer of silicon over a layer of silicon oxide, over an aluminum oxide window 103. Other implementations are within the scope of the current subject matter.

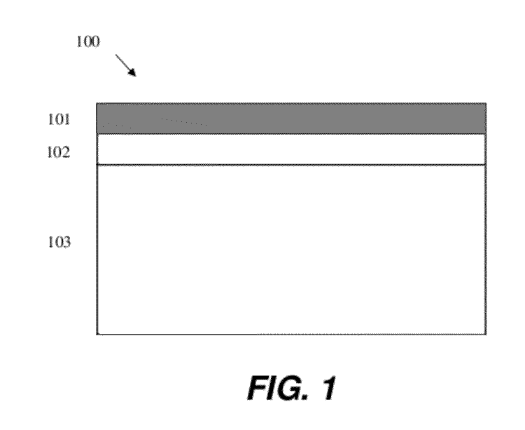

Referring to FIG. 1, an engineered substrate 100 includes a silicon layer 101, a silicon oxide layer 102, and an aluminum oxide window 103. Preferably the silicon layer 101 is between 100 and 1000 nm thick, though it can be between 100 and 200 nm thick, between 200 and 300 nm thick, between 400 and 500 nm thick, between 500 and 600 nm thick, between 600 and 700 nm thick, between 700 and 800 nm thick, between 800 and 900 nm thick, or between 900 and 1000 nm thick. Preferably the silicon oxide layer 102 is between 1 and 1000 nm thick, though it can be between 1 and 100 nm thick, between 100 and 200 nm thick, between 200 and 300 nm thick, between 400 and 500 nm thick, between 500 and 600 nm thick, between 600 and 700 nm thick, between 700 and 800 nm thick, between 800 and 900 nm thick, or between 900 and 1000 nm thick. Preferably the aluminum oxide window 103 is between 100 and 10,000 μm thick, though it can be between 100 and 1000 μm thick, between 1000 and 2000 μm thick, between 2000 and 3000 μm thick, between 4000 and 5000 μm thick, between 5000 and 6000 μm thick, between 6000 and 7000 μm thick, between 7000 and 8000 μm thick, between 8000 and 9000 μm thick, or between 9000 and 10,000 μm thick.

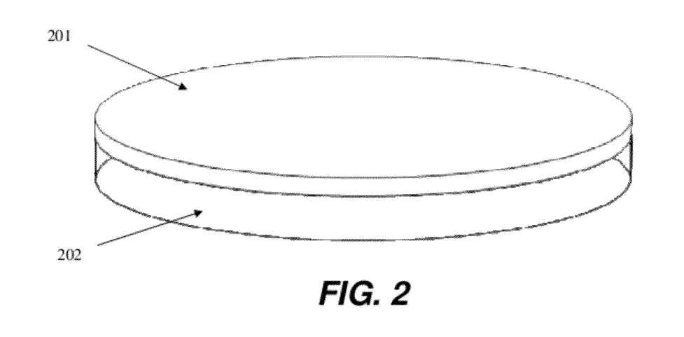

Other configurations are also possible. For example, referring to FIG. 2, at least a portion of the silicon oxide layer 201 can be deposited directly onto the aluminum oxide window 202. That is, the silicon oxide can be originally part of the silicon wafer, and/or it can be deposited onto the window before the silicon is bonded thereto.

Described herein is a method of making an engineered substrate for a GaN LED. A crystalline aluminum oxide (Al_{2O3}) window is provided. The window can be, for example, a single crystal or poly-crystalline. The window need not have any particular crystal orientation. A single crystal silicon wafer is also provided. The wafer can have a slight cut of between 0.01 and 1.0 degrees from the plane of the crystal.

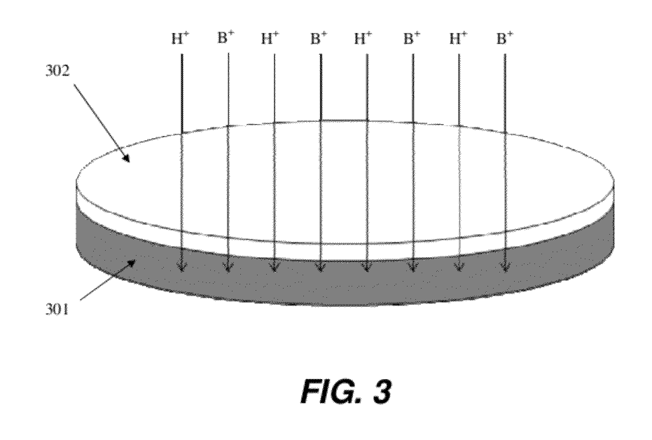

A layer of silicon oxide is preferably placed on the silicon wafer. The silicon oxide can be applied by thermal oxide, chemical oxide, or deposited oxide methods or by any method known in the art. Boron and/or hydrogen ions are then preferably implanted to a planned depth into the silicon 301 through the silicon oxide 302, as shown in FIG. 3. This can allow cleavage of the silicon at between 200 and 250 ° C. later on in the process.

The surfaces of the silicon oxide and the aluminum oxide window are then preferably plasma activated to promote bonding. This method uses the plasma implantation of O₂ or N₂ to promote bonding. Such methods are known in the art, for example, in Current et al., Surface and Coatings Technology, Volume 136, Issues 1-3, 2 Feb. 2001, Pages 138-141 and Husein et al., J. Phys. D: Appl. Phys. 33 (2000) 2869, incorporated herein, by reference, in their entireties.

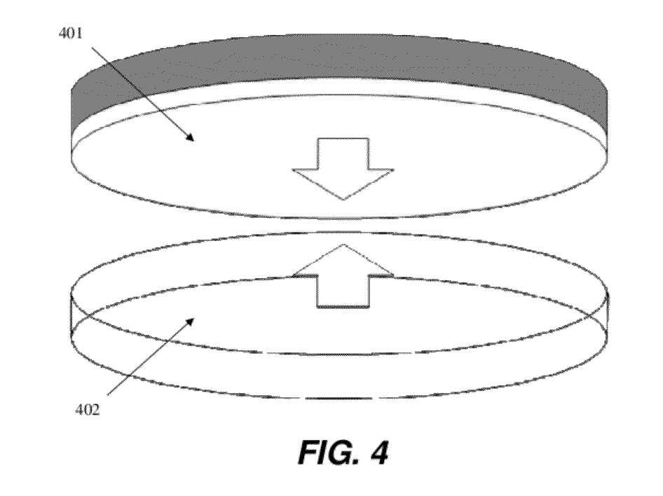

Referring to FIG. 4, the surfaces of the silicon oxide 401 and the aluminum oxide window 402 that have been plasma activated can be bonded together. The bonding temperature can be between 50 and 150° C. A uniform force is preferably applied to the layers to ensure full adhesion. A force of between approximately 5 and approximately 60 kN is preferably applied. The force can be applied for between one second and one hour. The bonded layers can then be annealed at an elevated temperature. This temperature can be up to 150° C. This step can be done with pressure applied or without pressure applied.

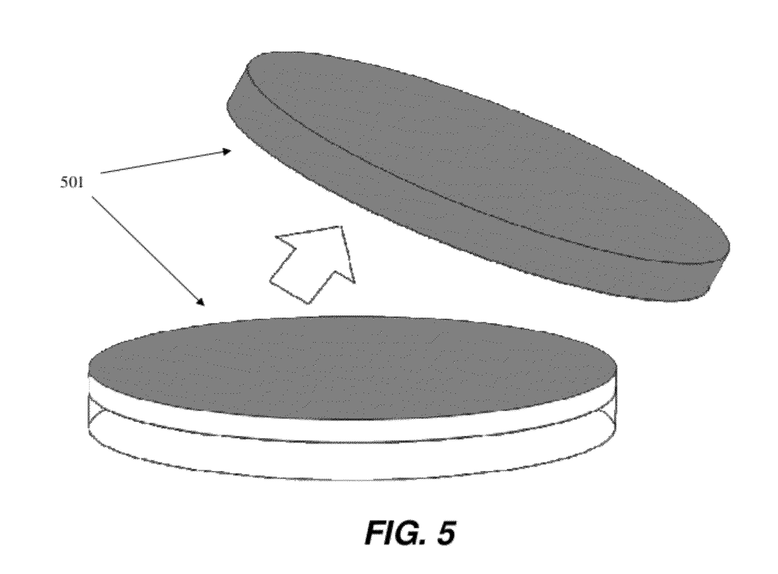

Referring to FIG. 5, the annealed stack is then preferably heated to between 200 and 250° C. This can cause the silicon wafer 501 to cleave near the depth where the boron and/or hydrogen ions implanted. The remaining silicon surface can then be etched using a buffered oxide etch, for example ammonium fluoride, hydrofluoric acid, and water.

Also, described herein is a method of making an engineered substrate for a GaN LED wherein the substrate is made up of a silicon oxide layer deposited directly onto an aluminum oxide window. A silicon oxide layer can be deposited on an aluminum oxide window. The silicon oxide may be applied by thermal oxide, chemical oxide, or deposited oxide methods, or by any method known in the art. The oxide layers can then be annealed at an elevated temperature. This temperature can be up to 150° C. This step can be done with pressure applied or without pressure applied. The surface of the silicon oxide can then be planarized using chemical-mechanical planarization (CMP) or by any similar process known in the art.

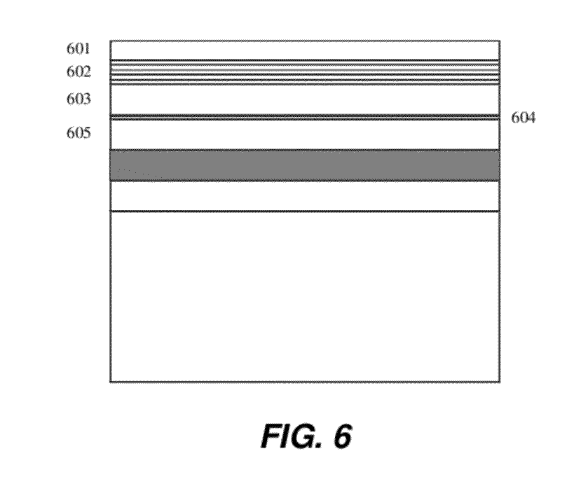

Further described herein is a method of using the engineered substrates described above. The substrates are generally subject to epitaxy to grow crystals on the silicon or silicon oxide layer. For example, FIG. 6 shows a p-doped Mg:GaN epitaxy layer 601, on a multiple quantum well InGaN epitaxy layers 602, on an n-doped Si:GaN epitaxy layer 603, on a partial coverage SiN_{X} mask layer 604, on an AlN seed layer 605.

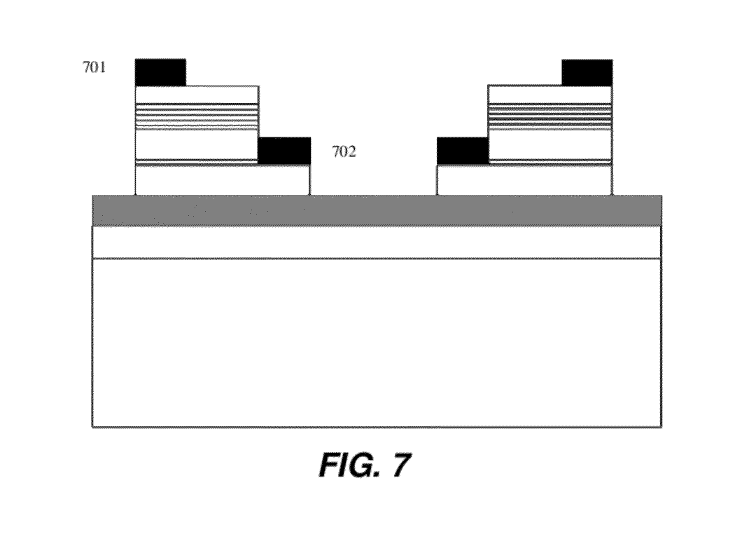

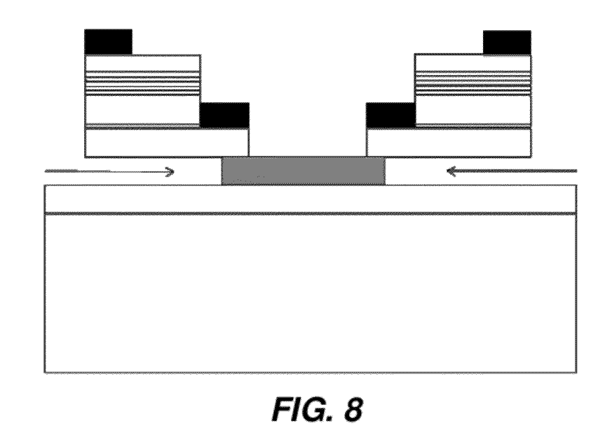

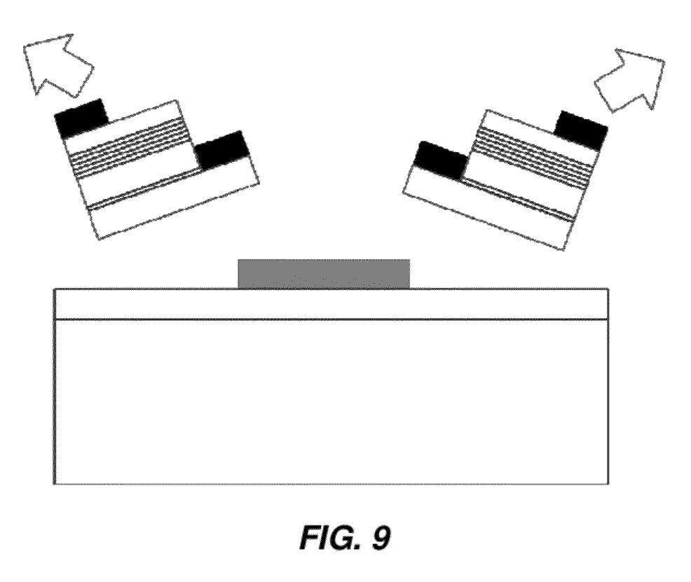

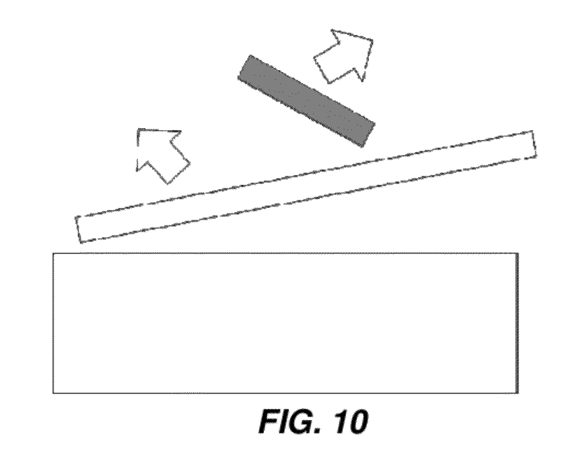

Referring to FIGS. 6-7, multiple lithography, etch, and metal deposition steps can be used to define the LED device from the initial epitaxy. For example, P-metal 701 and n-metal 702 can make up the p-n junction of the LED. This configuration can allow for easy removal of the LEDs from the substrate. The LEDs can be, for example, under etched, by removing silicon, as shown in FIG. 8. The LEDs can then easily removed, as shown in FIG. 9. The substrate itself can be recycled by removing the remaining silicon with a wet etch process and removing the silicon oxide layer from the aluminum oxide window using etching or polishing, as shown in FIG. 10.

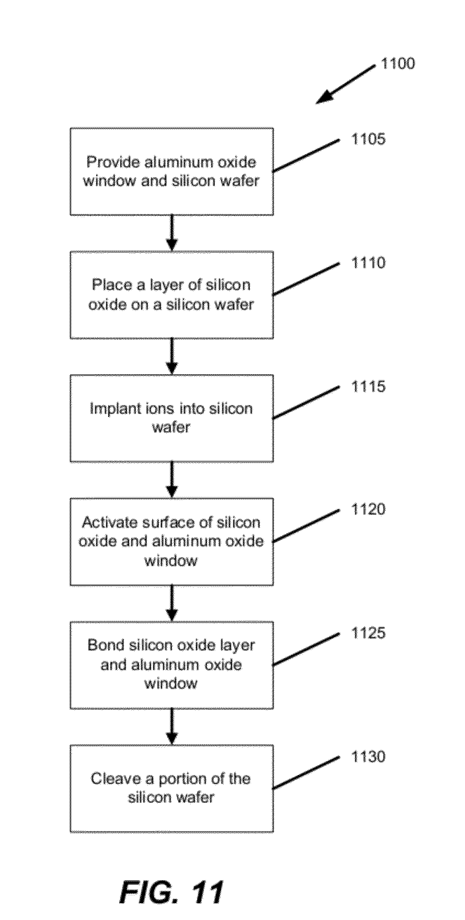

In operation, referring to FIG. 11, with further reference to FIGS. 1-5, a process 1100 for making an engineered substrate for a GaN LED includes the stages shown. The process 1100, however, is exemplary only and not limiting. The process 1100 may be altered, e.g., by having stages added, removed, altered, or rearranged.

At stage 1105, an aluminum oxide window is provided. Preferably, the window is a single crystal Al₂O₃ window, although a poly-crystalline window can also be used. The window may have a particular crystal orientation, although none is required. Alternatively, a single crystal silicon wafer can also be provided.

At stage 1110, a layer of silicon oxide is placed on the silicon wafer, and/or directly on the aluminum oxide window. The silicon oxide is preferably applied by thermal oxide, chemical oxide, or deposited oxide methods, all other methods may be used. This step can be accomplished with, or without pressure applied.

At stage 1115, the silicon wafer is implanted with ions. Preferably, the ions are boron ions and/or hydrogen ions. The ions are implanted to a predetermined depth in the silicon wafer. Preferably, the depth of the ions is determined by the depth at which a silicon wafer is desired to be cleaved at a later time.

At stage 1120, the surfaces of the silicon oxide and the aluminum oxide window are activated using plasma. Preferably, the activation promotes bonding between the layers.

At stage 1125, the surfaces of the silicon oxide in the aluminum oxide window that have been plasma activated are bonded together. The bonding preferably takes place at a temperature between 50 and 150° C., all other temperatures can be used. Preferably, a uniformed force of approximately 5-60 kN is applied, although other forces can be used. The force can be applied for varying times ranging from, for example, one second and one hour. At this stage, the women it can also be annealed at an elevated temperature of, for example, up to 150° C.

At stage 1130, a portion of the silicon wafer is cleaved from the stack. Cleaning is a compost by heating the stack to between 200 250° C., which causes the silicon wafer to cleave near the depth at which the ions were previously implanted. After clearing, the remaining silicon surface can be etched using a buffered oxide etch, or other etching techniques.

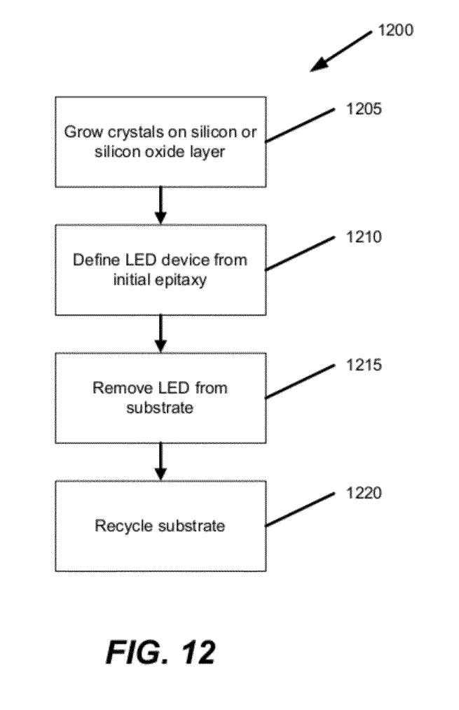

In operation, referring to FIG. 12, with further reference to FIGS. 6-10, a process 1200 for using the engineered substrates described above includes the stages shown. The process 1200, however, is exemplary only and not limiting. The process 1200 may be altered, e.g., by having stages added, removed, altered, or rearranged.

At stage 1205, crystals are grown on the silicon or silicon oxide layer. Preferably, epitaxy is used to grow the crystals. For example, p-doped Mg:GaN, n-doped Si:GaN, InGaN, and SiNx layers can be grown on an AlN seed layer.

At stage 1210, and LED device can be defined from the initial epitaxy using, for example, multiple lithography, etch, a metal deposition steps.

At stage 1215, the LED is removed from the substrate. The LED can be removed from the substrate by, for example, under etching the LED by removing silicon as shown in FIG. 8. After under etching the LED, the LED can be easily removed.

At optional stage 1120, the substrate can be recycled. Preferably, in order to recycle the substrate, the remaining silicon is removed from the substrate using a wet etch process and/or by polishing the substrate.

While this specification contains many specifics, these should not be construed as limitations on the scope of what is claimed or of what may be claimed, but rather as descriptions of features specific to particular variations. Certain features that are described in this specification in the context of separate variations can also be implemented in combination in a single variation. Conversely, various features that are described in the context of a single variation can also be implemented in multiple variations separately or in any suitable sub-combination. Moreover, although features may be described above as acting in certain combinations and even initially claimed as such, one or more features from a claimed combination can in some cases be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results. Only a few examples and implementations are disclosed. Variations, modifications and enhancements to the described examples and implementations and other implementations may be made based on what is disclosed.

Other implementations are within the scope and spirit of the current subject matter.

It is noted that one or more references are incorporated herein. To the extent that any of the incorporated material is inconsistent with the present disclosure, the present disclosure shall control. Furthermore, to the extent necessary, material incorporated by reference herein should be disregarded if necessary to preserve the validity of the claims.

What is claimed is:

1. A diode substrate comprising:
a crystalline aluminum oxide window;
a silicon oxide layer on the crystalline aluminum oxide window; and
a silicon layer on the silicon oxide layer, the silicon layer being implanted with ions at a predetermined depth.

2. The substrate of claim 1 wherein the silicon layer is between substantially 100 nm and substantially 1000 nm thick.

3. The substrate of claim 1 wherein the silicon oxide layer is between substantially 1 nm and substantially 1000 nm thick.

4. The substrate of claim 1 wherein the aluminum oxide window is between substantially 100 μm and substantially 10,000 μm thick.

5. The substrate of claim 1 wherein the silicon layer is cleaved at substantially the location of the implanted ions.

6. The substrate of claim 1 further comprising:
a laminate comprising an n-layer and a p-layer, the laminate being disposed on the silicon layer.

7. The substrate of claim 6 wherein the n-layer and p-layer laminate is configured as a light emitting diode.

8. A method of producing a diode substrate, the method comprising:
placing a layer of silicon oxide on a silicon wafer;
implanting ions through the silicon oxide to a predetermined depth in the silicon wafer;
activating one surface of each of the silicon oxide layer and an aluminum oxide window;
bonding the activated surfaces of the silicon oxide layer and the aluminum oxide window to form a stack;
annealing the stack; and
heating the stack to cause the silicon wafer to cleave at substantially the location of the implanted ions.

9. The method of claim 8 wherein the placing step includes placing a layer of silicon oxide on a silicon wafer by at least one of thermal oxide, chemical oxide, and deposited oxide methods.

10. The method of claim 8 wherein the ions are selected from the group consisting of Boron and Hydrogen ions.

11. The method of claim 8 wherein the activating includes activating the surfaces using plasma implantation of at least one of O₂ and N₂.

12. The method of claim 8 wherein the boding includes bonding at a temperature of between substantially 50° C. and substantially 150° C.

13. The method of claim 8 wherein the bonding includes applying a force of between substantially 5 kN and substantially 60 kN.

14. The method of claim 8 wherein the force is applied for between 1 second and 1 hour.

15. The method of claim 8 wherein the annealing takes place at a temperature less than substantially 150° C.

16. The method of claim 8 wherein heating the stack to cause the silicon wafer to cleave includes heating the stack to a temperature between substantially 200° C. and substantially 250° C.

17. The method of claim 8 further comprising etching a surface of the silicon layer using a buffered oxide etch.

18. The method of claim 8 further comprising epitaxially growing crystals on the silicon layer to form one or more additional layers on the stack.

19. The method of claim 18 wherein the one or more additional layers are selected from the group consisting of an n-layer and a p-layer.

20. The method of claim 18 wherein the crystals are chosen from the group consisting of Mg:GaN, InGaN, Si:GaN, and SiNₓ.

21. The method of claim 18 wherein the crystals are configured as a light emitting diode.

22. The method of claim 18 further comprising undercutting the silicon layer under the crystal layer to release the one or more additional layers from the stack.

23. The method of claim 22 further comprising, after the one or more additional layers are released from the stack, wet etching to remove any remaining silicon from the stack.

24. The method of claim 22 further comprising, after any remaining silicon is removed, removing the silicon oxide layer from the aluminum oxide window using at least one of etching and polishing.
